(19) United States
(12) Patent Application Publication
(10) Pub. No.: US 2021/0358992 A1
(43) Pub. Date: Nov. 18, 2021

(54) CMOS PIXEL SENSOR WITH EXTENDED FULL WELL CAPACITY

(71) Applicant: BAE Systems Imaging Solutions Inc., Nashua, NH (US)

(72) Inventors: Alberto M. Magnani, Danville, CA (US); John W. Ladd, Danville, CA (US)

(21) Appl. No.: 16/646,847

(22) PCT Filed: Jun. 3, 2019
(86) PCT No.: PCT/US19/35250

§ 371 Date: Mar. 12, 2020

(51) Int. Cl. H01L 27/146; H04N 5/378; H04N 5/355; H04N 5/363; H04N 5/3745

(52) U.S. Cl. CPC H01L 27/14643; H01L 27/14636; H04N 5/378; H04N 5/37455; H04N 5/363; H04N 5/35554; H04N 5/3559

(57) ABSTRACT

An imaging array and a method of operating an imaging array are disclosed. The imaging array includes a plurality of pixel sensors. At least one of the pixel sensors includes a photodiode, and a transfer gate connecting the photodiode to a floating diffusion node, a reset circuit, and a buffer adapted to generate a voltage indicative of a potential on the floating diffusion node on a bit line. The imaging array also includes a signal generator and a controller. The signal generator controls the potential at which electrons in the photodiode well are transferred to the floating diffusion node well. The controller causes the transfer gate signal generator to lower the potential on the transfer gate during an integration period such that electrons will be transferred from the photodiode well to the floating diffusion node well if the photodiode potential is less than the floating diffusion node potential.

### BACKGROUND

A typical CMOS pixel sensor includes a photodiode that is pre-charged to a reset voltage prior to an exposure to be measured. During the exposure, photoelectrons generated by the interaction of the light with the photodiode are captured in the depletion region of the photodiode. The captured electrons reduce the voltage on the photodiode. When the voltage on the photodiode decreases below some predetermined minimum, the photodiode can no longer accurately measure any additional light incident of that photodiode. The number of electrons needed to reach this point are referred to as the well capacity of the photodiode. The well capacity of a photodiode along with the noise floor determines the dynamic range over which the photodiode can be used to measure the light exposure. Here, the dynamic range is defined to be the ratio of the maximum charge that can be stored on the photodiode to the minimum charge that can be measured above the noise level.

Various schemes have been proposed for extending the dynamic range of a pixel sensor, as the simplest pixel sensors have insufficient dynamic range to measure many scenes of interest. One class of schemes generates an image of a scene by taking multiple photographs of the scene at different exposure levels and then combining the different exposures to produce one high dynamic range image of the scene. These schemes typically suffer from motion artifacts due to the movement of the camera or objects in the scene between exposures.

A second class of schemes utilizes pixel sensors which include two photodiodes, each having a different photo conversion efficiency. By combining the measurements of the two photodiodes, a high dynamic range picture can be generated. These schemes require additional areas of silicon for the imaging array. In addition, in some designs the individual photodiodes have different spectral responses which complicates the combining operation.

A third class of schemes utilizes a capacitor in each pixel sensor to accumulate photoelectrons that overflow from the photodiode. These schemes require the construction of a separate capacitor for each pixel sensor. The area required for these capacitors presents significant design challenges.

### SUMMARY

The system of the present disclosure includes an imaging array and a method of operating an imaging array. Broadly, the imaging array includes a plurality of pixel sensors. At least one of the pixel sensors includes a photodiode, and a transfer gate connecting the photodiode to a floating diffusion node, a reset circuit, and a buffer adapted to generate a voltage indicative of a potential on the floating diffusion node on a bit line. The photodiode is characterized by a photodiode well having a photodiode well capacity and a photodiode potential, and the floating diffusion node is characterized by a floating diffusion node well having a floating diffusion node well capacity and a floating diffusion node potential. The imaging array also includes a transfer gate signal generator and a controller. The transfer gate signal generator controls the transfer gate potential at which electrons in the photodiode well are transferred to the floating diffusion node well. The controller causes the transfer gate signal generator to lower the potential on the transfer gate during an integration period such that electrons will be transferred from the photodiode well to the floating diffusion node well if the photodiode potential is less than the floating diffusion node potential.

In one aspect, the transfer gate has a buried channel.

In another aspect, during the integration period, the controller causes the transfer gate signal generator to periodically switch the potential on the transfer gate between a first potential that blocks electrons from moving between the photodiode well and the floating diffusion node and a second potential that allows electrons to transfer between the photodiode well and the floating diffusion node well if the photodiode potential is less than the floating diffusion node potential.

In another aspect, the second potential allows electrons to be transferred if the photodiode well is at least half full.

In another aspect, the second potential allows electrons to be transferred if the photodiode well is at least three-quarters full.

In another aspect, the controller determines a first charge stored on the floating diffusion node and a second charge stored on the photodiode during a readout period following the integration period.

In another aspect, the controller provides an exposure value for the pixel based on a sum of the first and second charges if the second charge is greater than a threshold value, and the controller provides the exposure value based on the second charge without reference to the first charge if the first charge is less than the threshold.

The method for operating an imaging array that includes a plurality of pixel sensors, at least one of the pixel sensors includes a photodiode, and a transfer gate connecting the photodiode to a floating diffusion node, a reset circuit, and a buffer adapted to generate a voltage indicative of a potential on the floating diffusion node on a bit line. The photodiode is characterized by a photodiode well having a photodiode well capacity and a photodiode potential and the floating diffusion node is characterized by a floating diffusion node well having a floating diffusion node well capacity and a floating diffusion node potential and a transfer gate signal generator that controls a transfer gate potential on the transfer gate, the transfer gate potential determining a photodiode potential on the photodiode at which electrons in the photodiode well are transferred to the floating diffusion node well, includes resetting the photodiode and floating diffusion node to a reset potential; and setting a potential on the transfer gate that will allow electrons to flow from photodiode well to the floating diffusion node well if the photodiode potential is less than a first threshold and the floating diffusion node potential is greater than the photodiode potential during an integration period.

In one aspect, the method includes measuring a number of electrons stored in the floating diffusion node well and a number of electrons in the photodiode well during a readout period following the integration period, and computing an exposure for the pixel sensor from the number of electrons in the pixel photodiode well plus the number of electrons in the floating diffusion node if the number of electrons in the floating diffusion node well is greater than a second threshold or from the number of electrons in the photodiode well alone if the number of electrons in the floating diffusion node is less than or equal to the second threshold.

In another aspect, the method includes causing the transfer gate to periodically switch the potential on the transfer gate during an integration period between a first potential that blocks electrons from moving between the photodiode well and the floating diffusion node and a second potential that allows electrons to transfer between the photodiode well and the floating diffusion node well if the photodiode potential is less than the floating diffusion node potential.

In another aspect, the second potential allows electrons to be transferred if the photodiode well is at least half full.

In another aspect, the second potential allows electrons to be transferred if the photodiode well is at least three-quarters full.

### BRIEF DESCRIPTION OF THE DRAWINGS

FIG. 1 illustrates a two-dimensional imaging array according to one embodiment.

FIG. 2 is a schematic drawing of a pixel sensor in a column of pixel sensors and the associated column readout circuitry.

FIG. 3 is a timing diagram for the various control lines in FIG. 2 when the signal Tx is a binary signal such that gate 23 is either fully conducting or non-conducting.

FIGS. 4A-4C illustrate the basic principle by which the well capacity is expanded.

FIGS. 4D-4F illustrate the energy diagram at various phases of a high light intensity exposure with a pixel sensor according to one embodiment of the present disclosure.

FIGS. 5A-5E illustrate the energy levels in the photodiode and floating diffusion node wells.

FIGS. 6A-6C illustrate the energy levels in the photodiode and floating diffusion node wells of a pixel sensor that is illuminated with bright light during the integration period.

FIG. 7 illustrates the basic timing of some of the signal line shown in FIG. 2 during the readout and integration periods of pixel 11.

### DETAILED DESCRIPTION

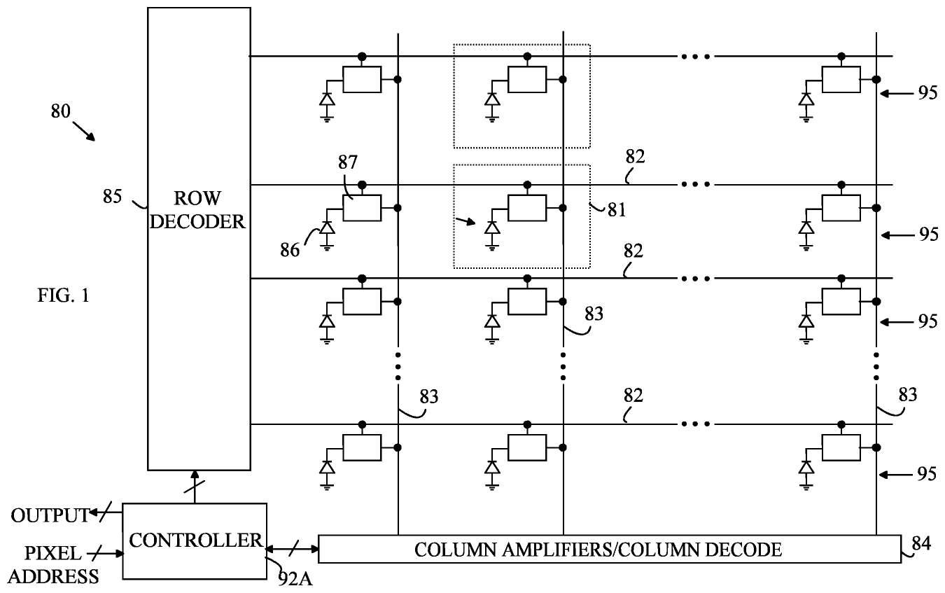

The manner in which a pixel sensor according to the present disclosure provides its advantages can be more easily understood with reference to an imaging array that utilizes a pixel sensor according to the present disclosure. FIG. 1 illustrates a two-dimensional imaging array according to one embodiment. Rectangular imaging array 80 includes a plurality of pixel sensors of which pixel sensor 81 is exemplary. Each pixel sensor has a photodiode 86. The manner in which the pixel sensor operates will be discussed in more detail below. The reset circuitry and amplification circuitry in each pixel is shown at 87. The pixel sensors are arranged as a plurality of rows and columns. Exemplary rows are shown at 95. Each pixel sensor in a column is connected to a readout line 83 that is shared by all of the pixel sensors in that column. Each pixel sensor in a row is connected to a row select line 82 which determines if the pixel sensor in that row is connected to the corresponding readout line.

The operation of rectangular imaging array 80 is controlled by a controller 92A that receives a pixel address to be read out. Controller 92A generates a row select address that is used by row decoder 85 to enable the read out of the pixel sensors on a corresponding row in rectangular imaging array 80. The column amplifiers are included in an array of column amplifiers 84 which execute the readout algorithm, which will be discussed in more detail below. All of the pixel sensors in a given row are read out in parallel; hence there is one column amplification and analog-to-digital converter (ADC) circuit per readout line 83. The column processing circuitry will be discussed in more detail below.

When rectangular imaging array 80 is reset and then exposed to light during an imaging exposure, each photodiode accumulates a charge that depends on the light exposure and the light conversion efficiency of that photodiode. That charge is converted to a voltage by reset and amplification circuitry 87 in that pixel sensor when the row in which the pixel sensor associated with that photodiode is read out. That voltage is coupled to the corresponding readout line 83 and processed by the amplification and ADC circuitry associated with the readout line in question to generate a digital value that represents the amount of light that was incident on the pixel sensor during the imaging exposure.

In general, an image is generated in two periods. The first period will be referred to as the integration period. During this period, the pixel sensors are illuminated with light from the scene being imaged and the photo-generated electrons are captured by the photodiodes in the pixel sensors. The second period will be referred to as the readout period. During this period, the captured electrons are measured and converted to a light intensity measurement.

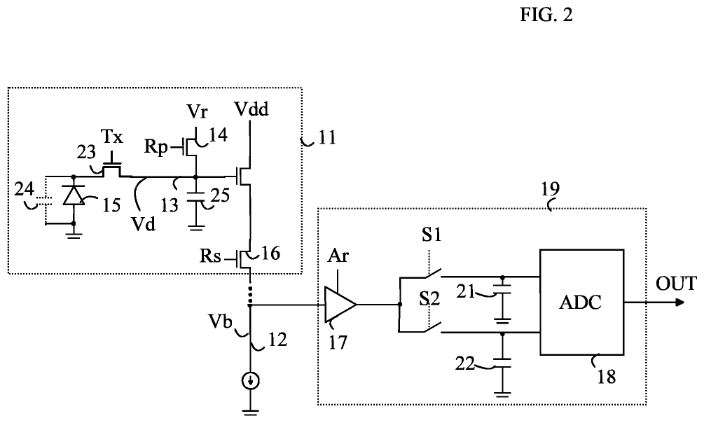

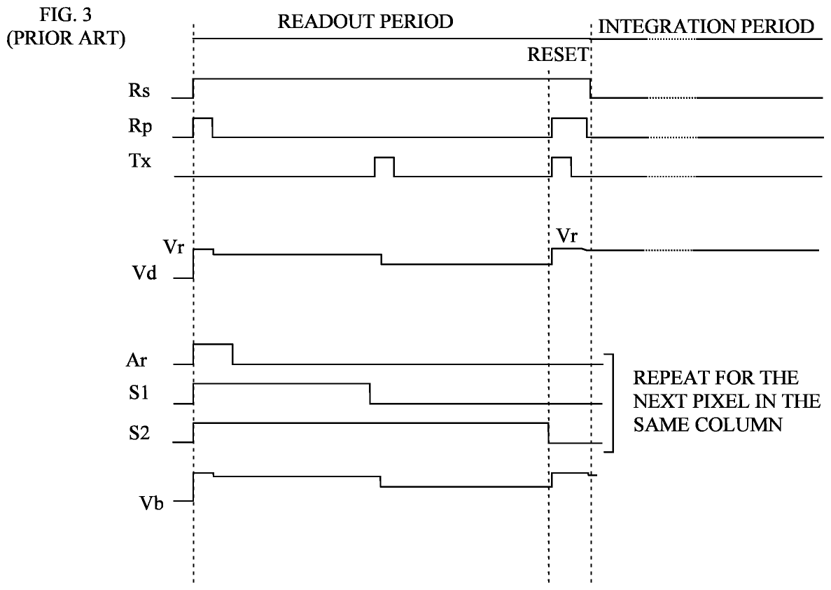

Refer now to FIGS. 2 and 3, which illustrate an embodiment of a pixel sensor according to the present disclosure in a column of pixel sensors. FIG. 2 is a schematic drawing of a pixel sensor in a column of pixel sensors and the associated column readout circuitry. Pixel sensor 11 differs from the typical prior art one photodiode pixel sensor in that the potential on control line Tx is varied during the image integration period of the imaging array in a manner that is discussed in more detail below.

The manner in which pixel sensor 11 is read out is more easily understood with reference to the manner in which a prior art pixel sensor is operated. FIG. 3 is a timing diagram for the various control lines in FIG. 2 when the signal Tx is a binary signal such that gate 23 is either fully conducting or non-conducting. Referring to FIG. 2, pixel sensor 11 is an exemplary pixel sensor in a column of pixel sensors that are connected to bit line 12. The specific pixel sensor in the column that is currently connected to bit line 12 is determined by a row select signal Rs that controls gate 16.

The voltage on bit line 12, Vb, during the readout period is read out via column readout circuit 19 which is configured for correlated double sampling. During the readout cycle for the row in which pixel sensor 11 is contained, the voltage on floating diffusion node 13, Vd, is measured after floating diffusion node 13 is reset to Vr and after the charge on photodiode 15 that accumulated during the exposure is transferred to floating diffusion node 13 via gate 23. The difference of these voltages is digitized by ADC 18 and is indicative of the charge that was accumulated during the exposure. After the charge accumulated in pixel sensor 11 is read out, floating diffusion node 13 is reset to Vr while gate 23 is in the conducting state. Gate 23 is then rendered non-conducting and a new exposure is commenced. During the readout, the two voltage readings are stored on capacitors 21 and 22. ADC 18 digitizes the difference in the two voltages.

The full well capacity of photodiode 15 is determined by the capacitance of capacitor 24 and the reset voltage. At the start of the exposure, capacitor 24 is charged to a voltage Vr. As photoelectrons are generated by photodiode 15, the charge on capacitor 24 is reduced. When a photocharge equal to Vr times the capacitance of capacitor 24 is generated, photodiode 15 will no longer be reversed biased and any further photoelectrons will be free to wander away from photodiode 15. Such wandering electrons give rise to blooming when the electrons are captured by adjacent photodiodes that are still reversed biased. Schemes for preventing this blooming can be created by adding another gate that allows the photocharge that is generated after the voltage is reduced to some predetermined voltage to be discharged to a power rail rather than being captured by an adjacent photodiode. However such themes are not central to the scheme taught in the present disclosure and hence will not be discussed in detail here.

In one aspect of a pixel sensor according to the present disclosure, the capacitance of the floating diffusion node is used to increase the full well capacity of the photodiode during the exposure. As noted above, the floating diffusion node has an inherent capacitance that is represented by capacitor 25 shown in FIG. 2. When photodiode 15 is reset by placing gates 14 and 23 in the conducting state and then placing gates 14 and 23 in the non-conducting state, capacitor 25 is left with a positive charge Vr*C₂₅, and hence, the floating diffusion node can assimilate Vr*C₂₅ worth of electrons. In a pixel sensor according to the present disclosure, gate 23 is biased such that gate 23 will allow photoelectrons to pass from capacitor 24 to capacitor 25 during the image integration period, thereby effectively increasing the full well capacity of photodiode 15.

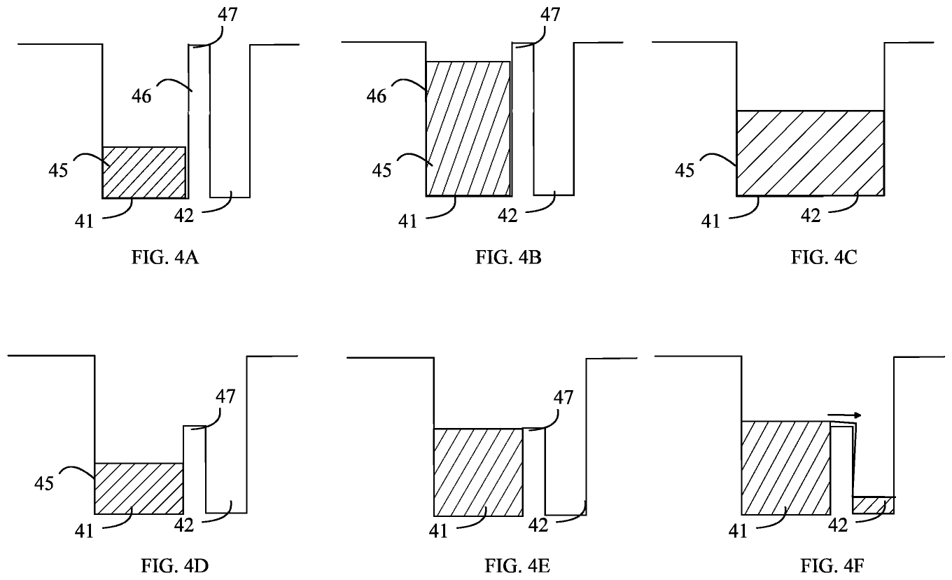

Refer now to FIGS. 4A-4C, which illustrate the basic principle by which the well capacity is expanded. FIG. 4A shows the energy distribution of the photodiode well 41 and the floating diffusion node well 42 as electrons 45 are accumulated during an integration period. The wells are separated by a potential barrier 46 which is created by the bias on the gate of transfer gate 23. The higher the voltage that is applied to the gate, the lower the potential barrier. As the exposure proceeds as shown in FIG. 4B, the electrons remain isolated in photodiode well 41. At the end of the readout period as shown in FIG. 4C, the potential barrier 47 has been removed and the electrons occupy both wells 41 and 42.

Refer now to FIGS. 4D-4F, which illustrate the energy diagram at various phases of a high light intensity exposure with a pixel sensor according to one embodiment of the present disclosure. Here, the potential barrier 47 has been reduced. The height of the barrier is chosen such that photoelectrons are initially contained in the photodiode well as shown in FIG. 4D. If there is sufficient light in the exposure, a point will be reached at which the electrons in the photodiode well have an energy that is exactly equal to that of the potential barrier 47 as shown in FIG. 4E. If there are additional photoelectrons generated past this point, photoelectrons from the photodiode well will spill over into the floating diffusion node well as shown in FIG. 4F. During readout, the electrons that spilled over into floating diffusion node well 42 are first measured and then removed from the floating diffusion node. The electrons that were isolated in the photodiode well are then measured as described below.

The maximum number of photoelectrons that can be accumulated during an integration period without leading to blooming is the sum of the capacities of the photodiode well and that of the floating diffusion node well. In the prior art represented by FIGS. 4A-4C, the non-blooming capacity is the capacity of the photodiode well.

The manner in which the pixel sensor is read out will now be discussed in more detail. At the end of the integration period, the photocharge generated by the photodiode is either located in the photodiode well or a combination of the two wells discussed above. To reduce the noise errors in reading out the accumulated photocharge, the two wells are read out separately and the results are then combined by the controller depending on the amount of photocharge that was measured. First, the charge, if any, that was transferred to the floating diffusion node during the integration period is read out. The voltage on the floating diffusion node at the end of the exposure is determined by this charge. To measure this voltage separately, gate 23 is placed in a full non-conducting state. Unfortunately, correlated double sampling cannot be used to reduce the readout noise in this measurement, and hence, this measurement is subject to higher noise. However, this higher noise is only encountered for exposures that utilize the higher well capacity, and hence, are subject to high shot noise, which can mask the higher noise in this case.

After the floating diffusion node is read out, the controller reads out the charge stored in the photodiode using the conventional correlated double sampling to measure the charge on the photodiode. First, the floating diffusion node is reset and the reset voltage is captured on one of the sample and hold capacitors. Gate 23 is then placed in the conducting state, and the voltage on the floating diffusion node is again measured and stored on one of the sample and hold capacitors. The difference in these voltages is then digitized.

For low light exposures, the charge on the floating diffusion node is consistent with noise and only the photodiode well is used to accumulate the photocharge, and hence, the pixel sensor has the same low noise as the conventional pixel sensor when the charge is below the level that would overflow into the floating diffusion node. At high light exposures, the shot noise in the measured photoelectrons is sufficiently large to mask the added readout noise.

Allowing a small current to flow through gate 23 can result in dark current issues if the current flows over an extended period of time. The dark current is the result of charge traps in the channel under the gate of gate 23. The dark current can be reduced by using a buried channel under gate 23 to avoid the photoelectrons being trapped. However, this solution requires higher gate voltages, and hence, is not preferred.

The dark current can be reduced by allowing the current to flow in “bursts” during the integration period. Rather than leaving the reduced potential barrier in place during the entire integration period, this embodiment periodically lowers the barrier to a level that determines the maximum exposure that is to be contained in the photodiode well and then returns the barrier to a higher level that inhibits charge from being transferred during the integration period.

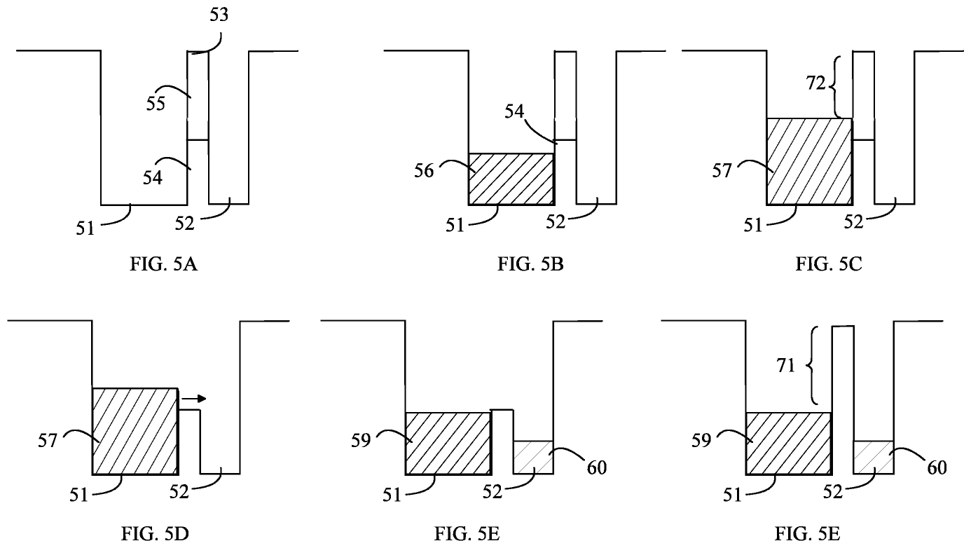

Refer now to FIGS. 5A-5E, which illustrate the energy levels in the photodiode and floating diffusion node wells. Since electrons are negatively charged and the wells are positively charged, a higher energy level in a well indicates that the voltage on that component is less. Referring to FIG. 5A, the energy barrier between photodiode well 51 and floating diffusion node well 52 is shown at 53. During the integration period, the potential barrier presented by gate 23 varies between level 55 and barrier level 54 as described below. Partially through the integration period, electrons will accumulate in photodiode well 51 as shown at 56 in FIG. 5B. The voltage on the photodiode is actually less than that on the floating diffusion node, both of which are being charged to a positive voltage. Since the potential within photodiode well 51 is less than the lower limit of the potential barrier, no charge will transfer to floating diffusion node well 52 when the potential is lowered to barrier level 54. Assume that the pixel sensor is receiving enough light that the potential in the photodiode well now exceeds the level of the barrier as shown in FIG. 5C. That is, the voltage on photodiode well 51 is less than the voltage on the floating diffusion node by an amount that is sufficient to allow charge to flow through gate 23 if the potential on gate 23 is lowered to the level corresponding to barrier level 54. At this point, the remaining capacity of the photodiode well to store additional charge without off-loading some of that charge to the floating diffusion node well is shown at 72. If the potential barrier is now lowered as shown in FIG. 5D, some of the charge 60 stored in the photodiode well will transfer to the floating diffusion node well leaving a residual charge 59 until potential 57 is lowered to barrier level as shown in FIG. 5E. Having emptied a portion of the photodiode well, the capacity of the photodiode well when the barrier potential is again raised is increased as shown at 71.

When the potential barrier is lowered, electrons will flow from the photodiode well to the floating diffusion node well until either the energy of the remaining electrons in the photodiode well drops to below that corresponding to barrier level 54 or the voltage on the photodiode well equals that on the floating diffusion node well. In the latter case, the amount of charge that moves from the photodiode well to the floating diffusion node well is the amount needed to equalize the voltage on the photodiode and floating diffusion node.

The frequency with which the photodiode well is partially “dumped” to the floating diffusion node well during the integration period depends on the maximum light intensity for which the pixel sensor is designed. If the time period between dumps is too long, the photodiode well will overflow out of the anti-blooming gate, and the pixel sensor will provide an inaccurate measure of the exposure. The maximum design light intensity sets the rate of charge per unit of time that is to be accommodated. The dump period needs to be set such that the well will not overflow when that charge rate is encountered between dumps. In principle, this problem can be avoided by leaving the potential barrier at barrier level 54 during the entire integration period. In this case, the excess charge is continuously shunted to the floating diffusion node well once the voltage on the photodiode drops to the level corresponding to barrier level 54. However, as noted above, this increases the dark current resulting from the charge traps in the transfer gate.

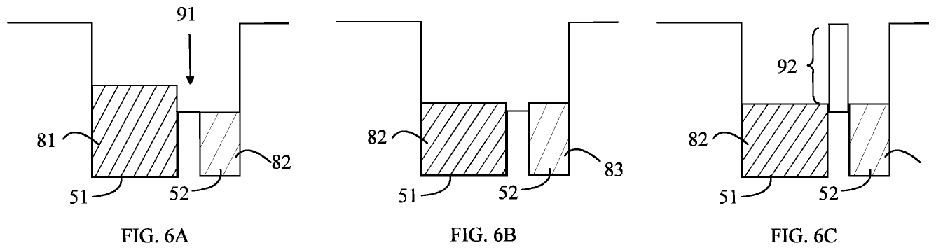

The above-described embodiment assumed that the potential barrier was reduced at regular intervals during the integration period. However, embodiments in which the photodiode well is dumped at more frequent intervals as the integration period proceeds can also be advantageously utilized. Refer now to FIGS. 6A-6C, which illustrate the energy levels in the photodiode and floating diffusion node wells of a pixel sensor that is illuminated with bright light during the integration period. Referring to FIG. 6A, it is assumed that the charge was previously transferred to the floating diffusion node in one or more earlier dump cycles, and hence, the potential in floating diffusion node well 52 is at or above the lowered barrier level and the potential in the photodiode well 51 is above the potential of the lowered barrier and the potential in floating diffusion node well 52. Thus, charge will be transferred from photodiode well 51 to floating diffusion node well 52; however, at the end of the charge transfer, the voltage on both of the wells will now be greater than that corresponding to the lower barrier potential as shown at FIG. 6B. When the barrier potential is again increased as shown in FIG. 6C, the available capacity of photodiode well 51 for controller 92A will be less than the capacity for the additional charge that would have been available if the potential in the floating diffusion node well had not been increased to above the lowered barrier potential.

From the above example, it will be apparent that as successive dump cycles transfer more and more charge to the floating diffusion node well, the remaining capacity of the photodiode well to receive additional charge will decrease further in these high light exposures. Hence, there is a possibility that the photodiode well will run out of space for additional photoelectrons before the next dump cycle even though there is additional space available in the floating diffusion node well. This potential problem can be mitigated by reducing the time between dump cycles as the integration period progresses. This problem can also be mitigated by decreasing the high potential barrier to a value just below the potential at which charge is shunted to the power rail by the anti-blooming circuit. Hence, charge will leak into the floating diffusion node well if the charge in the photodiode well gets too near the anti-blooming level. While this solution increases the dark current when the well is near capacity, the additional dark current can be masked by the high shot noise associated with such exposures.

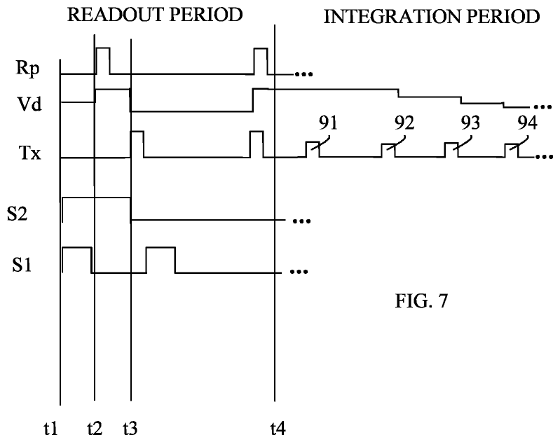

Refer now to FIG. 7, which illustrates the basic timing of some of the signal line shown in FIG. 2 during the readout and integration periods of pixel sensor 11. To simplify the drawing, signals associated with Rs, amplifier 17 and the control of ADC 18 have been omitted. At the start of the readout period, the charge that had been transferred to the floating diffusion node is read out by capturing the signal on the bit line on the sample and hold capacitor associated with switch S1 by closing S1 at t1. The reset voltage is then captured via S2 after pulsing Rp. The difference between the two captured voltages is digitized by ADC 18 and provides the controller with a measure of the charge that was transferred to the floating diffusion node during the previous exposure period. It should be noted that the reset voltage captured with S2 is also the voltage used for the correlated double sampling measurement for the charge that is still stored on the photodiode. Next, Tx is pulsed to transfer the charge stored on the photodiode to the floating diffusion node and the voltage on the floating diffusion node captured using S1 again. The difference between the charges stored on the sample and hold capacitors is now a measure of the charge that was stored on the photodiode at the end of the previous integration period.

After the charge from the previous integration period has been read out, the photodiode and the floating diffusion node are reset to the reset voltage by placing gates 14 and 23 in the conducting state using signals Rp and Tx. The photodiode and floating diffusion node are then isolated from the reset voltage by closing gates 14 and 23. The next integration period is then started at t4. During the integration period, gate 23 is pulsed with a signal on Tx that is sufficient to partially lower the energy barrier between the photodiode and the floating diffusion node as shown at 91-94. After the second pulse shown at 92, some charge was transferred to the floating diffusion node as indicated by the decrease in potential at node Vd. In this example, the time period between the Tx pulses decreases as the integration period proceeds for the reasons discussed above.

The increase in capacity of the pixel sensor according to the present disclosure depends on the relative capacities of the photodiode well and the floating diffusion node well. To properly read out the photodiode, the charge in the photodiode well must “fit” into the floating diffusion node well. Consider a full photodiode well. At read out, the floating diffusion node is charged to the reset voltage and connected to the photodiode. The decrease in voltage at the floating diffusion node measures the amount of charge that is transferred. If the floating diffusion node capacitance is much greater than the photodiode capacitance, the change in voltage will be reduced, and hence, the charge conversion efficiency of the pixel sensor will be reduced. Similarly, if the floating diffusion node well capacity is significantly smaller than the photodiode well capacity, the increase in overall capacity will be substantially reduced. Hence, the photodiode well capacity is preferably substantially equal to that of the floating diffusion node well. For the purposes of this application, the photodiode well capacity will be defined to be substantially equal to the floating diffusion node well capacity if the floating diffusion node capacity is 0.8 to 1.2 times the photodiode well capacity.

The minimum bias voltage during the exposure period determines the fraction of the photodiode well capacity that is reserved for low light exposures. As noted above, if the charge accumulated in the photodiode well does not cause the potential in the photodiode well to exceed the lowered barrier potential, the pixel sensor behaves substantially the same as a conventional pixel sensor, and has substantially the same low noise due to the correlated double sampling readout. Once the exposure generates sufficient photoelectrons to cause the potential to exceed this lowered barrier potential, the added noise associated with the read out of the overflow charge onto the floating diffusion node is encountered. For example, if the lowered barrier potential is set to provide half of the full photodiode well capacity to the low light exposure mode, the full well capacity of the pixel sensor is increased by a factor of two, while the low noise, low light exposure, well capacity is decreased by a factor of two. As noted above, as the potential of the lowered barrier is increased, the tolerance for a high intensity exposure to overflow the photodiode well before the excess charge is dumped to the floating diffusion node, is decreased. Hence, there is a tradeoff between the portion of the photodiode well that provides the low light exposure data and the ability to perform in high light exposures without an overflowing charge through the anti-blooming gate. In one exemplary embodiment, the lowered potential barrier is set to provide half of the photodiode well capacity to the low light mode. In another exemplary embodiment, the lowered potential barrier is set to provide three-quarters of the photodiode well capacity.

The above-described embodiments of the pixel sensor and imaging array according to the present disclosure have been provided to illustrate various aspects of the pixel sensor and imaging array. However, it is to be understood that different aspects of the pixel sensor and imaging array that are shown in different specific embodiments can be combined to provide other embodiments of the pixel sensor and imaging array. In addition, various modifications to the pixel sensor and imaging array will become apparent from the foregoing description and accompanying drawings. Accordingly, the pixel sensor and imaging array are to be limited solely by the scope of the following claims.

1. An imaging array comprising a plurality of pixel sensors, at least one of said pixel sensors comprising a photodiode, and a transfer gate connecting said photodiode to a floating diffusion node, a reset circuit, and a buffer adapted to generate a voltage indicative of a potential on said floating diffusion node on a bit line, said photodiode being characterized by a photodiode well having a photodiode well capacity and a photodiode potential and said floating diffusion node being characterized by a floating diffusion node well having a floating diffusion node well capacity and a floating diffusion node potential;
a transfer gate signal generator that controls a transfer gate potential that determines said photodiode potential at which electrons in said photodiode well are transferred to said floating diffusion node well; and
a controller that causes said transfer gate signal generator to lower said photodiode potential on said transfer gate during an integration period such that electrons will be transferred from said photodiode well to said floating diffusion node well if said photodiode potential is less than said floating diffusion node potential.

2. The imaging array of claim 1 wherein said transfer gate has a buried channel.

3. The imaging array of claim 1 wherein during said integration period, said controller causes said transfer gate signal generator to periodically switch said potential on said transfer gate between a first potential that blocks electrons from moving between said photodiode well and said floating diffusion node well and a second potential that allows electrons to transfer between said photodiode well and said floating diffusion node well if said photodiode potential is less than said floating diffusion node potential.

4. The imaging array of claim 3 wherein said second potential allows electrons to be transferred if said photodiode well is at least half full.

5. The imaging array of claim 3 wherein said second potential allows electrons to be transferred if said photodiode well is at least three-quarters full.

6. The imaging array of claim 1 wherein said controller determines a first charge stored on said floating diffusion node and a second charge stored on said photodiode during a readout period following said integration period.

7. The imaging array of claim 6 wherein said controller provides an exposure value for said pixel sensor based on a sum of said first and second charges if said second charge is greater than a threshold value, and said controller provides said exposure value based on said second charge without reference to said first charge if said first charge is less than said threshold value.

8. A method for operating an imaging array comprising a plurality of pixel sensors, at least one of said pixel sensors comprising a photodiode, and a transfer gate connecting said photodiode to a floating diffusion node, a reset circuit, and a buffer adapted to generate a voltage indicative of a potential on said floating diffusion node on a bit line, said photodiode being characterized by a photodiode well having a photodiode well capacity and a photodiode potential and said floating diffusion node being characterized by a floating diffusion node well having a floating diffusion node well capacity and a floating diffusion node potential and a transfer gate signal generator that controls a transfer gate potential on said transfer gate, said transfer gate potential determining a photodiode potential on said photodiode at which electrons in said photodiode well are transferred to said floating diffusion node well, said method comprising:
resetting said photodiode and floating diffusion node to a reset potential; and
setting said transfer gate potential such that will allow electrons to flow from photodiode well to said floating diffusion node well if said photodiode potential is less than a first threshold and said floating diffusion node potential is greater than said photodiode potential during an integration period.

9. The method of claim 8 further comprising measuring a number of electrons stored in said floating diffusion node well and a number of electrons stored in said photodiode well during a readout period following said integration period; and
computing an exposure for one of said pixel sensors from said number of electrons in said photodiode well plus said number of electrons in said floating diffusion node well if said number of electrons in said floating diffusion node well is greater than a second threshold or from the number of electrons in said photodiode well alone if said number of electrons in said floating diffusion node well is less than or equal to said second threshold.

10. The method of claim 8 further comprising causing said transfer gate to periodically switch said transfer gate potential during said integration period between a first potential that blocks electrons from moving between said photodiode well and said floating diffusion node well and a second potential that allows electrons to transfer between said photodiode well and said floating diffusion node well if said photodiode potential is less than said floating diffusion node potential.

11. The method of claim 10 wherein said second potential allows electrons to be transferred if said photodiode well is at least half full.

12. The method of claim 10 wherein said second potential allows electrons to be transferred if said photodiode well is at least three-quarters full.
